(19) United States
(12) Patent Application Publication
(10) Pub. No.: US 2007/0236859 A1
(43) Pub. Date: Oct. 11, 2007

(54) Organic encapsulant compositions for protection of electronic components

(76) Inventors: William J. Borland, Cary, NC (US); Thomas E. Dueber, Wilmington, DE (US); John D. Summers, Chapel Hill, NC (US); Olga L. Renovales, Apex, NC (US); Diptarka Majumdar, Cary, NC (US)

Correspondence Address: E I DU PONT DE NEMOURS AND COMPANY;LEGAL PATENT RECORDS CENTER, BARLEY MILL PLAZA 25/1128, 4417 LANCASTER PIKE, WILMINGTON, DE, 19805, US

(21) Appl. No.: 11/401,149

(22) Filed: Apr. 10, 2006

(51) Int. Cl. H01G 2/00; H05K 1/16

(52) U.S. Cl. 361/272; 174/260

(57) ABSTRACT

An organic encapsulant composition applied to formed-on-foil ceramic capacitors and embedded inside printed wiring boards allows the capacitor to resist printed wiring board chemicals and pass 1000 hours of accelerated life testing conducted under high humidity, elevated temperature and applied DC bias.

### FIELD OF THE INVENTION

This invention relates to compositions, and the use of such compositions for protective coatings. In one embodiment, the compositions are used to protect electronic device structures, particularly embedded fired-on-foil ceramic capacitors, from exposure to printed wiring board processing chemicals and for environmental protection.

### BACKGROUND OF THE INVENTION

Electronic circuits require passive electronic components such as resistors, capacitors, and inductors. A recent trend is for passive electronic components to be embedded or integrated into the organic printed circuit board (PCB). The practice of embedding capacitors in printed circuit boards allows for reduced circuit size and improved circuit performance. Embedded capacitors, however, must meet high reliability requirements along with other requirements, such as high yield and performance. Meeting reliability requirements involves passing accelerated life tests. One such accelerated life test is exposure of the circuit containing the embedded capacitor to 1000 hours at 85% relative humidity, 85° C. under 5 volts bias. Any significant degradation of the insulation resistance would constitute failure.

High capacitance ceramic capacitors embedded in printed circuit boards are particularly useful for decoupling applications. High capacitance ceramic capacitors may be formed by “fired-on-foil” technology. Fired-on-foil capacitors may be formed from thick-film processes as disclosed in U.S. Pat. No. 6,317,023B1 to Felten or thin-film processes as disclosed in U.S. Patent Publication 20050011857 A1 to Borland et al.

Thick-film fired-on-foil ceramic capacitors are formed by depositing a thick-film capacitor dielectric material layer onto a metallic foil substrate, followed by depositing a top copper electrode material over the thick-film capacitor dielectric layer and a subsequent firing under copper thick-film firing conditions, such as 900-950° C. for a peak period of 10 minutes in a nitrogen atmosphere.

The capacitor dielectric material should have a high dielectric constant (K) after firing to allow for manufacture of small high capacitance capacitors suitable for decoupling. A high K thick-film capacitor dielectric is formed by mixing a high dielectric constant powder (the “functional phase”) with a glass powder and dispersing the mixture into a thick-film screen-printing vehicle.

During firing of the thick-film dielectric material, the glass component of the dielectric material softens and flows before the peak firing temperature is reached, coalesces, encapsulates the functional phase, and finally forms a monolithic ceramic/copper electrode film.

The foil containing the fired-on-foil capacitors is then laminated to a prepreg dielectric layer, capacitor component face down to form an inner layer and the metallic foil may be etched to form the foil electrodes of the capacitor and any associated circuitry. The inner layer containing the fired-on-foil capacitors may now be incorporated into a multilayer printed wiring board by conventional printing wiring board methods.

The fired ceramic capacitor layer may contain some porosity and, if subjected to bending forces due to poor handling, may sustain some microcracks. Such porosity and microcracks may allow moisture to penetrate the ceramic structure and when exposed to bias and temperature in accelerated life tests may result in low insulation resistance and failure.

In the printed circuit board manufacturing process, the foil containing the fired-on-foil capacitors may also be exposed to caustic stripping photoresist chemicals and a brown or black oxide treatment. This treatment is often used to improve the adhesion of copper foil to prepreg. It consists of multiple exposures of the copper foil to caustic and acid solutions at elevated temperatures. These chemicals may attack and partially dissolve the capacitor dielectric glass and dopants. Such damage often results in ionic surface deposits on the dielectric that results in low insulation resistance when the capacitor is exposed to humidity. Such degradation also compromises the accelerated life test of the capacitor.

An approach to rectify these issues is needed. Various approaches to improve embedded passives have been tried. An example of an encapsulant composition used to reinforce embedded resistors may be found in U.S. Pat. No. 6,860,000 to Felten. A further example of an encapsulant composition to protect embedded resistors is found in U.S. patent application Ser. No. 10/754,348 to Summers et al.

### SUMMARY OF THE INVENTION

A fired-on-foil ceramic capacitor coated with an encapsulant and embedded in a printed wiring board structure is disclosed wherein said encapsulant provides protection to the capacitor from moisture and printed wiring board chemicals prior to and after embedding into the printed wiring board and said embedded capacitor structure passes 1000 hours of accelerated life testing conducted at 85° C., 85% relative humidity under 5 volts of DC bias.

Compositions are also disclosed comprising: an epoxy containing cyclic olefin resin with a water absorption of 2% or less; an epoxy catalyst; optionally one or more of an electrically insulated filler, a defoamer and a colorant and one or more organic solvents. The compositions have a cure temperature of 190° C. or less.

The invention is also directed to a method of encapsulating a fired-on-foil ceramic capacitor comprising: an epoxy-containing cyclic olefin resin with a water absorption of 2% or less, one or more phenolic resins with water absorption of 2% or less, an epoxy catalyst, optionally one or more of an inorganic electrically insulating filler, a defoamer and a colorant, and one or more of an organic solvent to provide an uncured composition; applying the uncured composition to coat a fired-on-foil ceramic capacitor; and curing the applied composition at a temperature of equal to or less than 190° C.

The inventive compositions containing the organic materials can be applied as an encapsulant to any other electronic component or mixed with inorganic electrically insulating fillers, defoamers, and colorants, and applied as an encapsulant to any electronic component.

According to common practice, the various features of the drawings are not necessarily drawn to scale. Dimensions of various features may be expanded or reduced to more clearly illustrate the embodiments of the invention.

### BRIEF DESCRIPTION OF THE DRAWINGS

FIG. 1A through 1G show the preparation of capacitors on commercial 96% alumina substrates that were covered by encapsulant compositions and used as a test vehicles to determine the encapsulant's resistance to selected chemicals.

FIG. 2A-2E show the preparation of capacitors on copper foil substrates that were covered by encapsulant.

FIG. 2F shows a plan view of the structure.

FIG. 2G shows the structure after lamination to resin.

FIG. 3A-FIG. 3J show the steps in the fabrication of printed wiring boards.

FIG. 4A-4L show the steps in the fabrication of printed wiring boards.

FIG. 5A-5N show the steps in the fabrication of printed wiring boards.

FIG. 5 L is a plan view of an etched foil structure containing fired on capacitors.

FIG. 5M show a step where, after forming a trench in the outer foil, one or more layers of encapsulant are printed onto the trench and dried then the encapsulant is cured.

FIG. 5N shows a plan view of the structure.

### DETAILED DESCRIPTION OF THE INVENTION

A fired-on-foil ceramic capacitor coated with an encapsulant and embedded in a printed wiring board is disclosed. The application and processing of the encapsulant is designed to be compatible with printed wiring board and integrated circuit (IC) package processes and provides protection to the fired-on-foil capacitor from moisture and printed wiring board fabrication chemicals prior to and after embedding into the structure. Application of said encapsulant to the fired-on-foil ceramic capacitor allows the capacitor embedded inside the printed wiring board to pass 1000 hours of accelerated life testing conducted at 85° C., 85% relative humidity under 5 volts of DC bias.

Compositions are disclosed comprising an epoxy-containing cyclic olefin resin with a water absorption of 2% or less, one or more phenolic resins with water absorption of 2% or less, an epoxy catalyst, an organic solvent, and optionally one or more of an inorganic electrically insulating filler, defoamer and colorant dye. The amount of water absorption was determined by ASTM D-570, which is a method known to those skilled in the art.

Applicants determined that the most stable polymer matrix is achieved with the use of crosslinkable resins that also have low moisture absorption of 2% or less, preferably 1.5% or less, more preferably 1% or less. Polymers used in the compositions with water absorption of 1% or less tend to provide cured materials with preferred protection characteristics.

The use of the crosslinkable composition of the invention provides important performance advantages over the corresponding non-crosslinkable polymers. The ability of the polymer to crosslink with crosslinking agents during a thermal cure can stabilize the binder matrix, raise the Tg, increase chemical resistance, or increase thermal stability of the cured coating compositions.

The crosslinkable compositions will include polymers selected from the group consisting of epoxy-containing cyclic olefin resins particularly epoxy-modified polynorbornene (Epoxy-PNB), dicyclopentadiene epoxy resin and mixtures thereof. Preferably, the Epoxy-PNB resin, available from Promerus as Avatrel™2390, or dicyclopentadiene epoxy resin used in the compositions will have water absorption of 1% or less.

The composition of the invention can include an Epoxy-PNB polymer comprising molecular units of formula I and II: 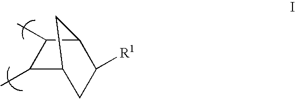
wherein R¹ is independently selected from hydrogen and a (C₁-C₁₀) alkyl. The term “alkyl” includes those alkyl groups with one to ten carbons of either a straight, branched or cyclic configuration. An exemplary list of alkyl groups include methyl, ethyl, propyl, isopropyl and butyl, and a PNB polymer with crosslinkable sites as depicted by molecular units of formula II: 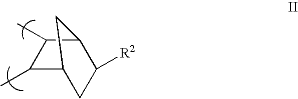
wherein R² is a pendant cross-linkable epoxy group and the molar ratio of molecular units of formula II to molecular units of formula I in the Epoxy-PNB polymer is greater than 0 to about 0.4, or greater than 0 to about 0.2. The crosslinkable epoxy group in the PNB polymer provides a site at which the polymer can crosslink with one or more crosslinking agents in the compositions of the invention as the compositions are cured. Only a small amount of crosslinkable sites on the PNB polymer is needed to provide an improvement in the cured material. For example, the compositions can include Epoxy-PNB polymers with a mole ratio as defined above that is greater than 0 to about 0.1.

Phenolic resins with water absorption of 2% or less are required to react with the epoxy to provide an effective moisture resistant material. An exemplary list of phenolic resins useful as thermal crosslinkers that can be used with the crosslinkable polymers include a dicyclopentadiene phenolic resin, and resins of cyclolefins condensed with phenolics. A dicyclopentadiene phenolic resin, available from Borden as Durite® ESD-1819, is depicted as:

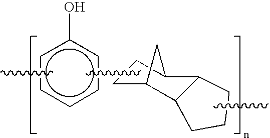

Applicants have also observed that the use of a crosslinkable Epoxy-PNB polymer in a composition can provide important performance advantages over the corresponding non-crosslinkable PNB polymers. The ability of the Epoxy-PNB polymer to crosslink with crosslinking agents during a thermal cure can stabilize the binder matrix, raise the Tg, increase chemical resistance, or increase thermal stability of the cured coating compositions.

The use of an epoxy catalyst that is not reactive at ambient temperatures is important to provide stability of the crosslinkable composition prior to being used. The catalyst provides catalytic activity for the epoxy reaction with the phenolic during the thermal cure. A catalyst that fulfills these requirements is dimethybenzylamine, and a latent catalyst that fulfills these requirements is dimethylbenzylammonium acetate, which is the reaction product of dimethylbenzylamine with acetic acid.

The compositions include an organic solvent. The choice of solvent or mixtures of solvents will depend in-part on the reactive resins used in the composition. Any chosen solvent or solvent mixtures must dissolve the resins and not be susceptible to separation when exposed to cold temperatures, for example. An exemplary list of solvents is selected from the group consisting of terpineol, ether alcohols, cyclic alcohols, ether acetates, ethers, acetates, cyclic lactones, and aromatic esters.

Most encapsulant compositions are applied to a substrate or component by screen printing a formulated composition, although stencil printing, dispensing, doctor blading into photoimaged or otherwise preformed patterns or other techniques known to those skilled in the art are possible.

Thick-film encapsulant pastes which are printed must be formulated to have appropriate characteristics so that they can be printed readily. Thick-film encapsulant compositions, therefore, include an organic solvent suitable for screen printing and optional additions of defoaming agents, colorants and finely divided inorganic fillers as well as the resins. The defoamers help to remove entrapped air bubbles after the encapsulant is printed. Applicants determined that silicone containing organic defoamers are particularly suited for defoaming after printing. The finely divided inorganic fillers impart some measure of thixotropy to the paste, thereby improving the screen printing rheology. Applicants determined that fumed silica is particularly suited for this purpose. Colorants may also be added to improve automated registration capability. Such colorants may be organic dye compositions, for example. The organic solvent should provide appropriate wettability of the solids and the substrate, have sufficiently high boiling point to provide long screen life and a good drying rate. The organic solvent along with the polymer also serves to disperse the finely divided insoluble inorganic fillers with an adequate degree of stability. Applicants determined that terpineol is particularly suited for the screen printable paste compositions of the invention. Additionally, the composition could comprise a photopolymer for photodefining the encapsulant for use with very fine features.

Generally, thick-film compositions are mixed and then blended on a three-roll mill. Pastes are typically roll-milled for three or more passes at increasing levels of pressure until a suitable dispersion has been reached. After roll milling, the pastes may be formulated to printing viscosity requirements by addition of solvent.

Curing of the paste or liquid composition is accomplished by any number of standard curing methods including convection heating, forced air convection heating, vapor phase condensation heating, conduction heating, infrared heating, induction heating, or other techniques known to those skilled in the art.

One advantage that the polymers provide to the compositions of the invention is a relatively low cure temperature. The compositions can be cured with a temperature of equal to or less than 190° C. over a reasonable time period. This is particularly advantageous as it is compatible with printing wiring board processes and avoids oxidation of copper foil or damage or degradation of component properties.

It is to be understood, that the 190° C. temperature is not a maximum temperature that may be reached in a curing profile. For example, the compositions can also be cured using a peak temperature up to about 270° C. with a short infrared cure. The term “short infrared cure” is defined as providing a curing profile with a high temperature spike over a period that ranges from a few seconds to a few minutes.

Another advantage that the polymers provide to the compositions of the inventions is a relatively high adhesion to prepreg when bonded to the prepreg using printed wiring board or IC package substrate lamination processes. This allows for reliable lamination processes and sufficient adhesion to prevent de-lamination in subsequent processes or use.

The encapsulant paste compositions of the invention can further include one or more metal adhesion agents. Preferred metal adhesion agents are selected from the group consisting of polyhydroxyphenylether, polybenzimidazole, polyetherimide, polyamideimide and 2-mercaptobenzimidazole (2-MB).

The compositions of the invention can also be provided in a solution and used in IC and wafer-level packaging as semiconductor stress buffers, interconnect dielectrics, protective overcoats (e.g., scratch protection, passivation, etch mask, etc.), bond pad redistribution, and solder bump underfills. One advantage provided by the compositions is the low curing temperature of less than 190° C. or short duration at peak temperature of 270° C. with short IR cure. Current packaging requires a cure temperature of about 300° C.+/−25° C.

As noted the composition(s) of the present invention are useful in many applications. The composition(s) may be used as protection for any electronic, electrical or non-electrical component. For example, the composition(s) may be useful in integrated circuit packages, wafer-level packages and hybrid circuit applications in the areas of semiconductor junction coatings, semiconductor stress buffers, interconnect dielectrics, protective overcoats for bond pad redistribution, “glob top’ protective encapsulation of semiconductors, or solder bump underfills. Furthermore, the compositions may be useful in battery automotive ignition coils, capacitors, filters, modules, potentiometers, pressure sensitive devices, resistors, switches, sensors, transformers, voltage regulators, lighting applications such as LED coatings for LED chip carriers and modules, sealing and joining medical and implantable devices, and solar cell coatings.

Test procedures used in the testing of the compositions of the invention and for the comparative examples are provided as follows:

Insulation Resistance

Insulation resistance of the capacitors is measured using a Hewlett Packard high resistance meter.

Temperature Humidity Bias (THB) Test

THB Test of ceramic capacitors embedded in printed wiring boards involves placing the printed wiring board in an environmental chamber and exposing the capacitors to 85° C., 85% relative humidity and a 5 volt DC bias. Insulation resistance of the capacitors is monitored every 24 hours. Failure of the capacitor is defined as a capacitor showing less than 50 meg-ohms in insulation resistance.

Brown Oxide Test

The device under test was exposed to an Atotech brown oxide treatment with a series of steps: (1) 60 sec. soak in a solution of 4-8% H₂SO₄ at 40° C., (2) 120 sec. soak in soft water at room temperature, (3) 240 sec soak in a solution of 3-4% NaOH with 5-10% amine at 60° C., (4) 120 sec. soak in soft water at room temperature, (5) 120 sec. soak in 20 ml/l H₂O₂ and H₂SO₄ base with additive at 40° C., (6) a soak for 120 sec. in a solution of Part A 280, Part B 40 ml/l at 40° C., and (7) a deionized water soak for 480 sec. at room temperature.

Insulation resistance of the capacitor was then measured after the test and failure was defined as a capacitor showing less than 50 Meg-Ohms.

Black Oxide Test

Black oxide processes are similar nature and scope to the brown oxide procedures described above, however the acid and base solutions in a traditional black oxide process can possess concentrations as high as 30%. Thus, the reliability of encapsulated dielectrics was evaluated after exposure to 30% sulfuric acid and 30% caustic solutions, 2 minute and 5 minute exposure times respectively.

Corrosion Resistance Test

Samples of the encapsulant are coated on copper foil and the cured samples were placed in a fixture that contacts the encapsulant coated side of the copper foil to 3% NaCl solution in water that was heated to 60° C. A 2V and 3V DC bias was applied respectively during this test. The corrosion resistance (Rₚ) was monitored periodically during a 10-hour test time.

Water Permeation Test

Samples of the encapsulant were coated on copper foil and the cured samples wee placed in a fixture that contacts the encapsulant coated side of the copper foil to 3% NaCl solution in water that was heated to 60° C. No bias was applied during this test. The water permeation rate indicated by a capacitance resistance was monitored periodically during a 10-hour test time.

The following glossary contains a list of names and abbreviations for each ingredient used:
PNB Polynorbornene Appear-3000B from Promerus LLC of Brecksville, Ohio; Tg 330° C., 0.03% moisture absorption
Epoxy-PNB Epoxy-containing polynorbornene from Promerus LLC of Brecksville, Ohio; Mw of 74,000, Mn of 30,100
Durite ESD-1819 Dicyclopentadiene phenolic resin from Borden Chemical, Inc. of Louisville, Ky.
Fumed silica High surface area silica obtainable from several sources, such as Degussa.
Organosiloxane antifoam agent Defoaming agent SWS-203 obtainable from Wacker Silicones Corp.

### EXAMPLES

### Example 1

An encapsulant composition was prepared according to the following composition and procedure:

| Material | Weight % |
|---|---|
| Epoxy-PNB pre-dissolved in | 23.37 |
| dibutyl carbitol at 50.0% solids | |
| ESD-1819 pre-dissolved in | 23.37 |
| dibutyl carbitol at 50.0% solids | |
| N,N-dimethylbenzylammonium | 0.47 |
| acetate | |
| Titanium dioxide powder | 31.67 |
| Alumina powder | 21.12 |

The mixture was roll milled with a 1-mil gap with 3 passes each at 0, 50, 100, 200, 250 and 300 psi to yield well dispersed paste.

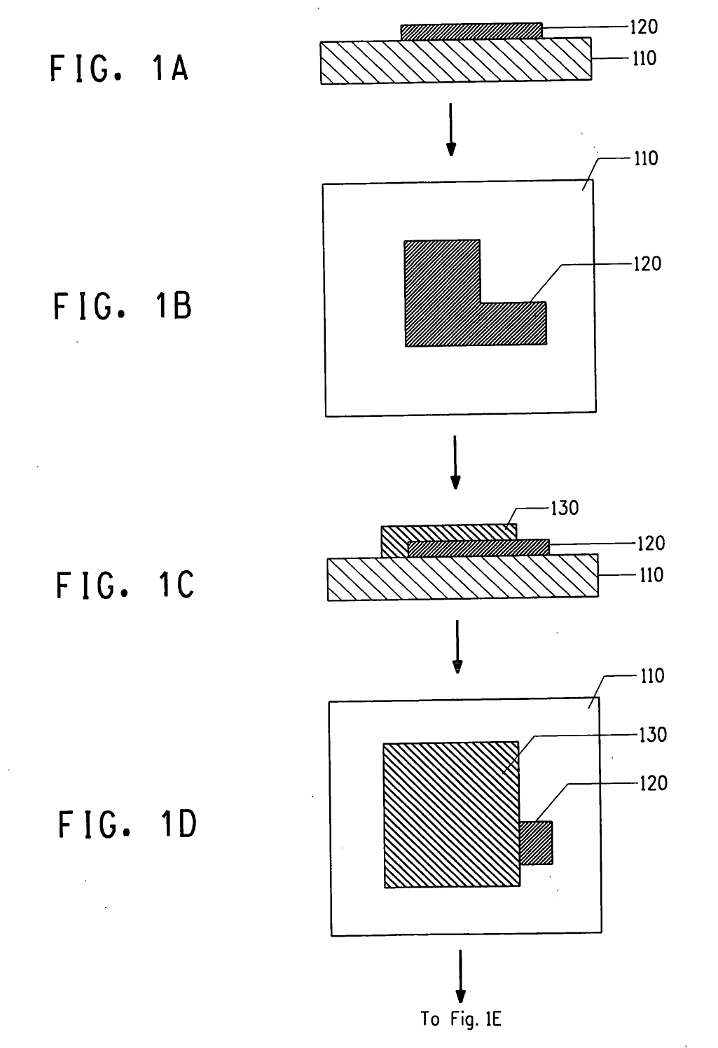

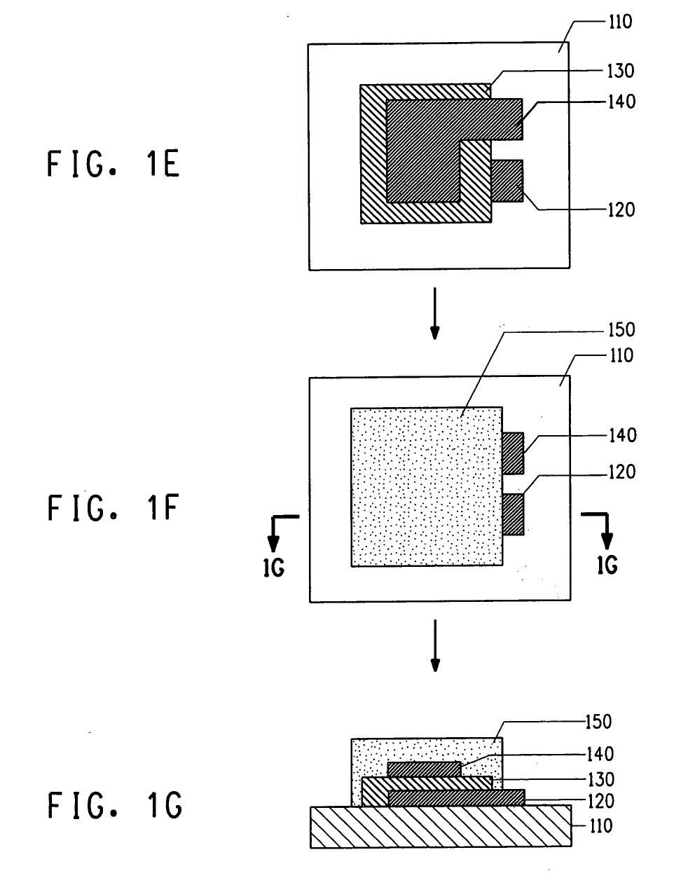

Capacitors on commercial 96% alumina substrates were covered by encapsulant compositions and used as a test vehicle to determine the encapsulants resistance to selected chemicals. The test vehicle was prepared in the following manner as schematically illustrated in FIG. 1A through 1G.

As shown in FIG. 1A, electrode material (EP 320 obtainable from E. I. du Pont de Nemours and Company) was screen-printed onto the alumina substrate to form electrode pattern 120. As shown in FIG. 1B, the area of the electrode was 0.3 inch by 0.3 inch and contained a protruding “finger” to allow connections to the electrode at a later stage. The electrode pattern was dried at 120° C. for 10 minutes and fired at 930° C. under copper thick-film nitrogen atmosphere firing conditions.

As shown in FIG. 1C, dielectric material (EP 310 obtainable from E.I. du Pont de Nemours and Company) was screen-printed onto the electrode to form dielectric layer 130. The area of the dielectric layer was approximately 0.33 inch by 0.33 inch and covered the entirety of the electrode except for the protruding finger. The first dielectric layer was dried at 120° C. for 10 minutes. A second dielectric layer was then applied, and also dried using the same conditions. A plan view of the dielectric pattern is shown in FIG. 1D.

As shown in FIG. 1E, copper paste EP 320 was printed over the second dielectric layer to form electrode pattern 140. The electrode was 0.3 inch by 0.3 inch but included a protruding finger that extended over the alumina substrate. The copper paste was dried at 120° C. for 10 minutes.

The first dielectric layer, the second dielectric layer, and the copper paste electrode were then co-fired at 930° C. under copper thick-film firing conditions.

The encapsulant composition was screen printed through a 400 mesh screen over the entirety of the capacitor electrode and dielectric except for the two fingers using the pattern shown in FIG. 1F to form a 0.4 inch by 0.4 inch encapsulant layer 150. The encapsulant layer was dried for 10 minutes at 120° C. Another layer of encapsulant was printed and dried for 10 minutes at 120° C. A side view of the final stack is shown in FIG. 1G. The two layers of encapsulant were then baked under nitrogen in a forced draft oven at 170° C. for 1 hr followed by a ramp up to 230° C. and held for 5 minutes. The final cured thickness of the encapsulant was approximately 10 microns.

In a water permeation test, the encapsulant film capacitance remained unchanged during an immersion time of >450 minutes. In a corrosion resistance test, the corrosion resistance (Rₚ) remained unchanged after an immersion time of 9 hours. The adhesion of the encapsulant was measured to be 2.2 pounds/inch over the copper electrode and 3.0 pounds/inch over the capacitor dielectric.

### Example 2

An encapsulant composition was prepared using the following ingredients and processes:

### Preparation of Epoxy Medium

Ingredients:

| | |
|---|---|
| Terpineol | 300 g |
| Avatrel 2390 epoxy resin (AV2390) | 200 g |

A 1 liter resin kettle was fitted with a heating jacket, mechanical stirrer, nitrogen purge, thermometer, and addition port. The terpineol was added to the kettle and heated to 40° C. After the terpineol reached 40° C., the epoxy was added through the addition port to the stirring solvent. After complete addition, the powder gradually dissolved to yield a clear and colorless solution of moderate viscosity. Complete dissolution of the polymer took approximately two hours. The medium was then cooled to room temperature and discharged from the reactor. The solid content of the finished medium was analyzed by heating a known quantity of medium for two hours at 150° C. The solids content was determined to be 40.33% by this method. The viscosity of the medium was also determined to be 53.2 Pa·S. at 10 rpm using a Brookfield Viscometer 2HA, utility cup and number 14 spindle.

### Preparation of Phenolic Medium

Ingredients:

| | |
|---|---|
| Terpineol | 300 g |
| Durite ESD-1819 phenolic resin (ESD1819) | 200 g |

A resin kettle was fitted with a heating mantle, mechanical stirrer, nitrogen purge, thermometer, and addition port. The terpineol was added to the kettle and preheated to 80° C. The phenolic resin was crushed with a morter and pestle then added to the terpineol with stirring. After complete addition, the powder gradually dissolved to yield a dark red solution of moderate viscosity. Complete dissolution of the polymer took approximately one hour. The medium was then cooled to room temperature and discharged from the reactor. The solid content of the finished medium was analyzed by heating a known quantity of medium for two hours at 150° C. The solids content was determined to be 40.74% by this method. The viscosity of the medium was also determined to be 53.6 Pa·S. at 10 rpm using a Brookfield Viscometer 2HA, utility cup and number 14 spindle.

Preparation of an Encapsulant Paste Containing 16% Degussa R7200 Fumed Silica:

Ingredients:

| | | |
|---|---|---|
| Epoxy medium | 12.4 | g |
| Phenolic medium | 12.4 | g |
| Degussa R7200 fumed silica | 5.0 | g |
| Terpineol | 2.4 | g |
| Organosiloxane antifoam agent | 0.2 | g |
| Benzyldimethylammonium acetate | 0.1 | g |

The epoxy medium, phenolic medium, organosiloxane, and catalyst were combined in a suitable container and hand-stirred for approximately 5 minutes to homogenize the ingredients. The silica was then added in three equal aliquots with hand stirring followed by vacuum mixing at low agitation between each addition. After complete addition of the silica, the crude paste was vacuum mixed for 15 minutes with medium agitation. After mixing, the paste was three roll milled according to the following schedule:

| | Feed roll | Apron roll |
|---|---|---|
| Pass | pressure (psi) | pressure (psi) |
| 1 | 0 | 0 |
| 2 | 0 | 0 |
| 3 | 100 | 100 |
| 4 | 200 | 100 |
| 5 | 300 | 200 |
| 6 | 400 | 300 |

Terpineol was then added to the finished paste with stirring to modify the paste viscosity and make it suitable for screen printing.

The encapsulant composition was screen printed through a 400 mesh screen over the capacitor electrode and dielectric using the pattern 150 shown in FIG. 1F. It was dried for 10 minutes at 120° C. Another layer of encapsulant was printed and dried for 60 minutes at 120° C. The two layers of encapsulant were then cured in air at 170° C. for 90 minutes followed by a short “spike” cure of 15 minutes at 200° C. in air. The final cured thickness of the encapsulant was approximately 10 microns.

After encapsulation, the average capacitance of the capacitors was 42.5 nF, the average loss factor was 1.5%, the average insulation resistance was 1.2 Gohms. The coupons were then dipped in a 5% sulfuric acid solution at room temperature for 6 minutes, rinsed with deionized water, then dried at 120° C. for 30 minutes. The average capacitance, loss factor, and insulation resistance were 42.8 nf, 1.5%, 1.1 Gohm respectively after the acid treatment.

Three inch squares of the encapsulant paste were also printed and cured on 6″ square one oz. copper sheets to yield defect-free coatings suitable for corrosion resistance testing as described above. The coatings were exposed for 12 hours to a 3% NaCl solution under 2V and 3V DC bias. The corrosion resistance remained above 7×10⁹ ohms·cm² at 0.01 Hz, during the test.

### Example 3

An encapsulant was prepared with the same composition as described in example 2 except the Degussa R7200 fumed silica was substituted by Cabot Cab-O-Sil TS-530 fumed silica. The encapsulant was prepared according to the procedure outlined in Example 2

The encapsulant was printed and cured over the capacitors prepared on alumina substrates as described in Example 2. After encapsulation, the average capacitance of the capacitors was 39.2 nF, the average loss factor was 1.5%, the average insulation resistance was 2.3 Gohms. The coupons were then dipped in a 5% sulfuric acid solution at room temperature for 6 minutes, rinsed with deionized water, then dried at 120° C. for 30 minutes. The average capacitance, loss factor, and insulation resistance were 42.3 nf, 1.5%, 2.6 Gohms respectively after the acid treatment.

### Example 4

An encapsulant was prepared with the same composition as described in example 2 except the Degussa R7200 fumed silica was substituted by Cabot CAB-OHS-5 fumed silica. The encapsulant was prepared according to the procedure outlined in Example 2.

The encapsulant was printed and cured over the capacitors prepared on alumina substrates as described in Example 2. After encapsulation, the average capacitance of the capacitors was 39.9 nF, the average loss factor was 1.6%, the average insulation resistance was 3. Gohms. The coupons were then dipped in a 5% sulfuric acid solution at room temperature for 6 minutes, rinsed with deionized water, then dried at 120° C. for 30 minutes. The average capacitance, loss factor, and insulation resistance were 40.3 nf, 1.6%, 2.8 Gohms respectively after the acid treatment.

### Example 5

An encapsulant was prepared with the same composition as described in example 2 except the Degussa R7200 fumed silica was substituted by Cabot Cab-O-Sil TS-500 fumed silica. The encapsulant was prepared according to the procedure outlined in Example 2.

The encapsulant was printed and cured over the capacitors prepared on alumina substrates as described in Example 2. After encapsulation, the average capacitance of the capacitors was 40.2 nF, the average loss factor was 1.5%, the average insulation resistance was 2.2 Gohm. The coupons were then dipped in a 5% sulfuric acid solution sat room temperature for 6 minutes, rinsed with deionized water, then dried at 120° C. for 30 minutes. The average capacitance, loss factor, insulation resistance were 41.8 nf, 1.5%, 2.4 Gohm respectively after the acid treatment.

### Example 6

An encapsulant with the following composition containing 13% by weight Degussa R7200 fumed silica was prepared according to the procedure outlined in Example 2.

| | | |
|---|---|---|
| Epoxy medium | 40 | g |
| Phenolic medium | 14.2 | g |
| Degussa R7200 fumed silica | 8.1 | g |
| Terpineol | 2.4 | g |
| Organosiloxane antifoam agent | 0.31 | g |
| Benzyldimethylammonium acetate | 0.15 | g |

The encapsulant was printed and cured over the capacitors prepared on alumina substrates as described in Example 2. After encapsulation, the average capacitance of the capacitors was 40.4 nF, the average loss factor was 1.5%, the average insulation resistance was 3.2 Gohm. The coupons were then dipped in a 5% sulfuric acid solution at room temperature for 6 minutes, rinsed with deionized water, then dried at 120° C. for 30 minutes. The average capacitance, loss factor, and insulation resistance were 40.8 nf, 1.5%, 2.9 Gohms respectively after the acid treatment.

### Example 7

An encapsulant with the following composition containing 8% by weight Degussa R7200 fumed silica was prepared according to the procedure outlined in Example 2.

| | | |
|---|---|---|
| Epoxy medium | 12.4 | g |
| Phenolic medium | 12.4 | g |
| Degussa R7200 fumed silica | 2.4 | g |
| Organosiloxane antifoam agent | 0.2 | g |
| Benzyldimethylammonium acetate | 0.12 | g |

The encapsulant was printed and cured over the capacitors prepared on alumina substrates as described in Example 2. After encapsulation, the average capacitance of the capacitors was 35.1 nF, the average loss factor was 1.5%, the average insulation resistance was 2.0 Gohms. The coupons were then dipped in a 30% sulfuric acid solution at 45° C. for 2 minutes, rinsed with deionized water, then dried at 120° C. for 30 minutes. The average capacitance, loss factor, and insulation resistance were 35.7 nf, 1.6%, 2.0 Gohms respectively after the acid treatment.

### Example 8

An encapsulant was prepared with the same composition as described in example 7 except the Degussa R7200 fumed silica was substituted by Cabot Cab-O-Sil TS-530 fumed silica. The encapsulant was prepared according to the procedure outlined in Example 2.

The encapsulant was printed and cured over the capacitors prepared on alumina substrates as described in Example 2. After encapsulation, the average capacitance of the capacitors was 35.5 nF, the average loss factor was 1.5%, the average insulation resistance was 3.0 Gohms. The coupons were then dipped in a 30% sulfuric acid solution at 45° C. for 2 minutes, rinsed with deionized water, then dried at 120° C. for 30 minutes. The average capacitance, loss factor, and insulation resistance (Gohm) were 36.3 nf, 1.6%, 1.9 Gohm respectively after the acid treatment.

### Example 9

An encapsulant was prepared with the same composition as described in example 7 except the Degussa R7200 fumed silica was substituted by Cabot CAB-OHS-5 fumed silica fumed silica. The encapsulant was prepared according to the procedure outlined in Example 2.

The encapsulant was printed and cured over the capacitors prepared on alumina substrates as described in Example 2. After encapsulation, the average capacitance of the capacitors was 35.5 nF, the average loss factor was 1.4%, the average insulation resistance was 3.6 Gohms. The coupons were then dipped in a 30% sulfuric acid solution at 45° C. for 2 minutes, rinsed with deionized water, then dried at 120° C. for 30 minutes. The average capacitance, loss factor, and insulation resistance were 36.3 nf, 1.5%, 2.4 Gohms respectively after the acid treatment.

Three inch squares of the encapsulant paste were also printed and cured on 6″ square one oz. copper sheets to yield defect-free coatings suitable for corrosion resistance testing as described above. The coatings were exposed for 12 hours to a 3% NaCl solution under 2V and 3V DC bias. The corrosion resistance remained above 7×10⁹ ohms·cm² at 0.01 Hz, during the test.

### Example 10

An encapsulant was prepared with the same composition as described in example 7 except the Degussa R7200 fumed silica was substituted by Cabot Cab-O-Sil TS-500 fumed silica. The encapsulant was prepared according to the procedure outlined in Example 2.

The encapsulant was printed and cured over the capacitors prepared on alumina substrates as described in Example 2. After encapsulation, the average capacitance of the discrete dielectrics was 33 nF, the average loss factor was 1.4%, the average insulation resistance was 3.3 Gohms. The coupons were then dipped in a 30% sulfuric acid solution at 45° C. for 2 minutes, rinsed with deionized water, then dried at 120° C. for 30 minutes. The average capacitance, loss factor, and insulation resistance were 33.8 nf, 1.5%, 2.2 Gohm respectively after the acid treatment.

### Example 11

An encapsulant with the following composition containing 8% by weight Degussa R7200 fumed silica was prepared according to the procedure outlined in Example 2.

| | | |
|---|---|---|
| Epoxy medium | 40.0 | g |
| Phenolic medium | 14.2 | g |
| Degussa R7200 fumed silica | 4.9 | g |
| Organosiloxane antifoam agent | 0.36 | g |
| Benzyldimethylammonium acetate | 0.13 | g |

The encapsulant was printed and cured over the capacitors prepared on alumina substrates as described in Example 2. To evaluate the encapsulant stability in the presence of strong acids and bases, selected coupons were then dipped in a 30% sulfuric acid solution at 45° C. for 2 minutes, rinsed with deionized water, then dried at 120° C. for 30 minutes. Additional coupons were exposed to a 30% sodium hydroxide bath at 60° C. for 5 minutes. After exposure, these coupons were also rinsed with deionized water and dried prior to testing. The table below summarizes capacitor properties before and after acid and base exposure.

| | | | Insulation |
|---|---|---|---|
| | Capacitance | Dissipation | Resistance |
| Condition | (nF) | Factor (%) | (Gohm) |
| After encapsulation | 33.5 | 1.4 | 4.4 |
| After base treatment | 34.9 | 1.5 | 5.1 |
| After acid treatment | 34.0 | 1.4 | 2.7 |

### Example 12

An encapsulant was prepared with the same composition as described in example 11 except the Degussa R7200 fumed silica was substituted by Cabot Cab-O-Sil TS-530 fumed silica. The encapsulant was prepared according to the procedure outlined in Example 2.

The encapsulant was printed and cured over the capacitors prepared on alumina substrates as described in Example 2. To evaluate the encapsulant stability in the presence of strong acids and bases, selected coupons were then dipped in a 30% sulfuric acid solution at 45° C. for 2 minutes, rinsed with deionized water, then dried at 120° C. for 30 minutes. Additional coupons were exposed to a 30% sodium hydroxide bath at 60° C. for 5 minutes. After exposure, these coupons were also rinsed with deionized water and dried prior to testing. The table below summarizes capacitor properties before and after acid and base exposure.

| | | | Insulation |
|---|---|---|---|
| | Capacitance | Dissipation | Resistance |
| Condition | (nF) | Factor (%) | (Gohm) |
| After encapsulation | 43.6 | 1.4 | 2.0 |
| After base treatment | 44.4 | 1.4 | 1.9 |
| After acid treatment | 44.1 | 1.4 | 3.3 |

### Example 13

An encapsulant was prepared with the same composition as described in example 11 except the Degussa R7200 fumed silica was substituted by Cabot CAB-OHS-5 fumed silica. The encapsulant was prepared according to the procedure outlined in Example 2.

The encapsulant was printed and cured over the capacitors prepared on alumina substrates as described in Example 2. To evaluate the encapsulant stability in the presence of strong acids and bases, selected coupons were then dipped in a 30% sulfuric acid solution at 45° C. for 2 minutes, rinsed with deionized water, then dried at 120° C. for 30 minutes. Additional coupons were exposed to a 30% sodium hydroxide bath at 60° C. for 5 minutes. After exposure, these coupons were also rinsed with deionized water and dried prior to testing. The table below summarizes capacitor properties before and after acid and base exposure.

Three inch squares of the encapsulant paste were also printed and cured on 6″ square one oz. copper sheets to yield defect-free coatings suitable for corrosion resistance testing as described above. The coatings were exposed for 12 hours to a 3% NaCl solution under 2V and 3V DC bias. The corrosion resistance remained above 7×10⁹ ohms·cm² at 0.01 Hz, during the test.

| | | | Insulation |
|---|---|---|---|
| | Capacitance | Dissipation | Resistance |
| Condition | (nF) | Factor (%) | (Gohm) |
| After encapsulation | 34.2 | 1.5 | 5.2 |
| After base treatment | 34.5 | 1.6 | 2.6 |
| After acid treatment | 35.4 | 1.5 | 3.7 |

### Example 14

An encapsulant was prepared with the same composition as described in example 11 except the Degussa R7200 fumed silica was substituted by Cabot Cab-O-Sil TS-500 fumed silica. The encapsulant was prepared according to the procedure outlined in Example 2

The encapsulant was printed and cured over the capacitors prepared on alumina substrates as described in Example 2. To evaluate the encapsulant stability in the presence of strong acids and bases, selected coupons were then dipped in a 30% sulfuric acid solution at 45° C. for 2 minutes, rinsed with deionized water, then dried at 120° C. for 30 minutes. Additional coupons were exposed to a 30% sodium hydroxide bath at 60° C. for 5 minutes. After exposure, these coupons were also rinsed with deionized water and dried prior to testing. The table below summarizes capacitor properties before and after acid and base exposure.

Three inch squares of the encapsulant paste were also printed and cured on 6″ square one oz. copper sheets to yield defect-free coatings suitable for corrosion resistance testing as described above. The coatings were exposed for 12 hours to a 3% NaCl solution under 2V and 3V DC bias. The corrosion resistance remained above 7×10⁹ ohms·cm² at 0.01 Hz, during the test.

| | | | Insulation |
|---|---|---|---|
| | Capacitance | Dissipation | Resistance |
| Condition | (nF) | Factor (%) | (Gohm) |
| After encapsulation | 37.3 | 1.4 | 3.6 |
| After base treatment | 36.8 | 1.4 | 3.8 |
| After acid treatment | 43.0 | 1.4 | 2.4 |

### Example 15

An encapsulant with the following composition containing 2% by weight Degussa R7200 fumed silica was prepared according to the procedure outlined in Example 2.

| | | |
|---|---|---|
| Epoxy medium | 40.0 | g |
| Phenolic medium | 14.2 | g |
| Degussa R7200 fumed silica | 1.2 | g |
| Organosiloxane antifoam agent | 0.36 | g |
| Benzyldimethylammonium acetate | 0.13 | g |

The encapsulant was printed and cured over the capacitors prepared on alumina substrates as described in Example 2. To evaluate the encapsulant stability in the presence of strong acids and bases, selected coupons were then dipped in a 30% sulfuric acid solution at 45° C. for 2 minutes, rinsed with deionized water, then dried at 120° C. for 30 minutes. Additional coupons were exposed to a 30% sodium hydroxide bath at 60° C. for 5 minutes. After exposure, these coupons were also rinsed with deionized water and dried prior to testing. The table below summarizes capacitor properties before and after acid and base exposure.

| | | | Insulation |
|---|---|---|---|
| | Capacitance | Dissipation | Resistance |
| Condition | (nF) | Factor (%) | (Gohm) |
| After encapsulation | 42.3 | 1.4 | 3.2 |
| After base treatment | 42.6 | 1.4 | 3.6 |
| After acid treatment | 43.6 | 1.4 | 2.5 |

### Example 16

An encapsulant was prepared with the same composition as described in example 15 except the Degussa R7200 fumed silica was substituted by Cabot Cab-O-Sil TS-530 fumed silica. The encapsulant was prepared according to the procedure outlined in Example 2.

The encapsulant was printed and cured over the capacitors prepared on alumina substrates as described in Example 2. To evaluate the encapsulant stability in the presence of strong acids and bases, selected coupons were then dipped in a 30% sulfuric acid solution at 45° C. for 2 minutes, rinsed with deionized water, then dried at 120° C. for 30 minutes. Additional coupons were exposed to a 30% sodium hydroxide bath at 60° C. for 5 minutes. After exposure, these coupons were also rinsed with deionized water and dried prior to testing. The table below summarizes capacitor properties before and after acid and base exposure.

| | | | Insulation |
|---|---|---|---|
| | Capacitance | Dissipation | Resistance |
| Condition | (nF) | Factor (%) | (Gohm) |
| After encapsulation | 42.6 | 1.5 | 3.4 |
| After base treatment | 42.7 | 1.5 | 5.3 |
| After acid treatment | 41.6 | 1.5 | 3.1 |

### Example 17

An encapsulant was prepared with the same composition as described in example 15 except the Degussa R7200 fumed silica was substituted by Cabot CAB-OHS-5 fumed silica. The encapsulant was prepared according to the procedure outlined in Example 2.

The encapsulant was printed and cured over the capacitors prepared on alumina substrates as described in Example 2. To evaluate the encapsulant stability in the presence of strong acids and bases, selected coupons were then dipped in a 30% sulfuric acid solution at 45° C. for 2 minutes, rinsed with deionized water, then dried at 120° C. for 30 minutes. Additional coupons were exposed to a 30% sodium hydroxide bath at 60° C. for 5 minutes. After exposure, these coupons were also rinsed with deionized water and dried prior to testing. The table below summarizes capacitor properties before and after acid and base exposure.

| | | | Insulation |
|---|---|---|---|
| | Capacitance | Dissipation | Resistance |
| Condition | (nF) | Factor (%) | (Gohm) |
| After encapsulation | 35.2 | 1.4 | 5.1 |
| After base treatment | 34.5 | 1.5 | 4.4 |
| After acid treatment | 35.2 | 1.4 | 3.9 |

### Example 18

An encapsulant was prepared with the same composition as described in example 15 except the Degussa R7200 fumed silica was substituted by Cabot Cab-O-Sil TS-500 fumed silica. The encapsulant was prepared according to the procedure outlined in Example 2.

The encapsulant was printed and cured over the capacitors prepared on alumina substrates as described in Example 2. To evaluate the encapsulant stability in the presence of strong acids and bases, selected coupons were then dipped in a 30% sulfuric acid solution at 45° C. for 2 minutes, rinsed with deionized water, then dried at 120° C. for 30 minutes. Additional coupons were exposed to a 30% sodium hydroxide bath at 60° C. for 5 minutes. After exposure, these coupons were also rinsed with deionized water and dried prior to testing. The table below summarizes capacitor properties before and after acid and base exposure.

| | | | Insulation |
|---|---|---|---|
| | Capacitance | Dissipation | Resistance |
| Condition | (nF) | Factor (%) | (Gohm) |
| After encapsulation | 41.4 | 1.4 | 3.6 |
| After base treatment | 40.5 | 1.4 | 3.2 |
| After acid treatment | 41.3 | 1.5 | 3.5 |

### Example 19

### Comparative Example

A paste identical in composition to example 14 was prepared by substituting the Avatrel epoxy resin with SU-8, an epoxidized phenolic resin from Resolution Products based on bisphenol-A. The SD-1819 phenolic resin was replaced with a standard phenol-formaldehyde resin, Epikote 154, also from Resolution Products. The solvent, terpineol, was also changed to butyl carbitol to improve the solubility of these selected resins. The recipe is detailed below:

| | | |
|---|---|---|
| SU-8 Epoxy resin | 5.0 | g |
| Epikote 154 phenolic resin | 5.0 | g |
| Butyl carbitol acetate solvent | 14.8 | g |
| Cabot Cab-O-Sil TS-500 fumed silica | 2.4 | g |
| Organosiloxane processing aid | 0.2 | g |
| Benzyldimethylammonium acetate | 0.12 | g |

The paste was printed, cured and evaluated as illustrated in Example 2. The table below summarizes capacitor properties before and after acid and base exposure.

| | | | Insulation |
|---|---|---|---|
| | Capacitance | Dissipation | Resistance |
| Condition | (nF) | Factor (%) | (Gohm) |
| After encapsulation | 38.2 | 1.5 | 3.1 |
| After base treatment | 36.3 | 1.8 | 0.08 |
| After acid treatment | 35.6 | 1.7 | 0.06 |

Three inch squares of the encapsulant paste were also printed and cured on 6″ square one oz. copper sheets to yield defect-free coatings suitable for corrosion resistance testing as described above. The coatings were exposed for 12 hours to a 3% NaCl solution under 2V and 3V DC bias. The corrosion resistance decreased from greater than 7×10⁹ ohms·cm² to 7×10⁵ ohms·cm² at 0.01 Hz, during the test, indicating a substandard encapsulant.

### Example 20

A paste identical in composition to Example 14 was prepared by substituting the Avatrel epoxy resin with SU-8, an epoxidized phenolic resin from Resolution Products based on bisphenol-A. The SD-1819 phenolic resin was replaced with a conventional cresol novolac resin, also from Resolution Products, known at Epikote 156. The solvent, terpineol, was also changed to butyl carbitol to improve the solubility of these selected resins. A detailed list of ingredients is summarized below.

| | | |
|---|---|---|
| SU-8 Epoxy resin | 5.0 | g |
| Epon 164 cresol novolac resin | 5.0 | g |
| Butyl carbitol acetate solvent | 14.8 | g |
| Cabot Cab-O-Sil TS-500 fumed silica | 2.4 | g |
| Organosiloxane processing aid | 0.2 | g |
| Benzyldimethylammonium acetate | 0.12 | g |

The paste was printed, cured and evaluated as illustrated in Example 2. The table below summarizes capacitor properties before and after acid and base exposure.

| | | | Insulation |
|---|---|---|---|
| | Capacitance | Dissipation | Resistance |
| Condition | (nF) | Factor (%) | (Gohm) |
| After encapsulation | 37.2 | 1.4 | 2.8 |
| After base treatment | 35.1 | 1.7 | 0.09 |
| After acid treatment | 36.9 | 1.9 | 0.10 |

### Example 21

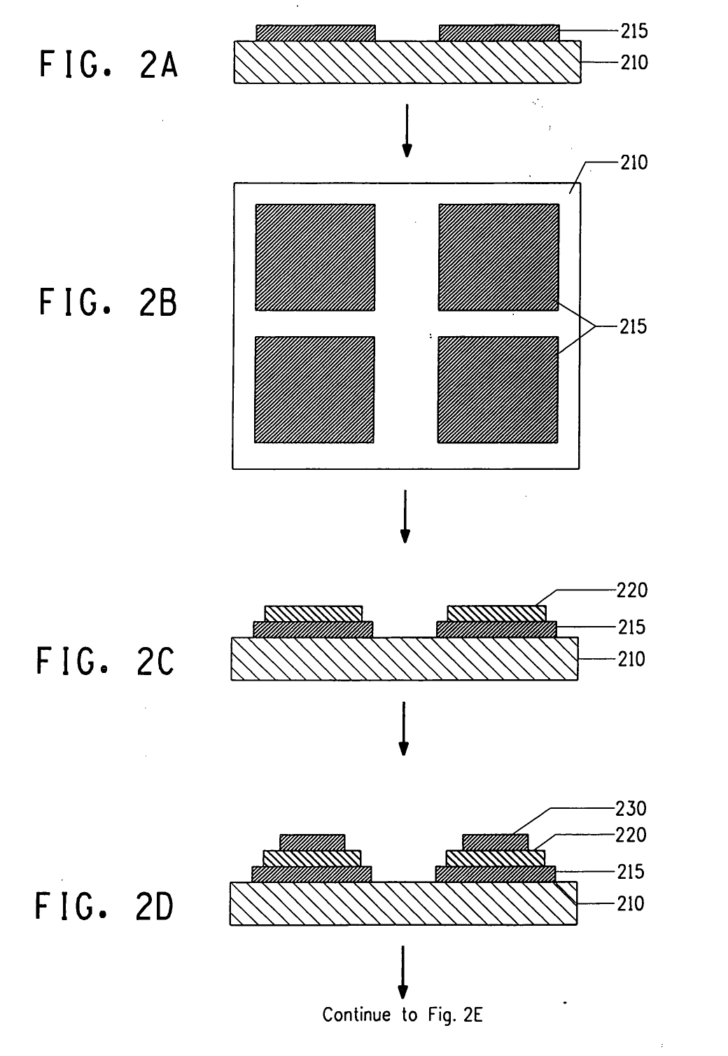

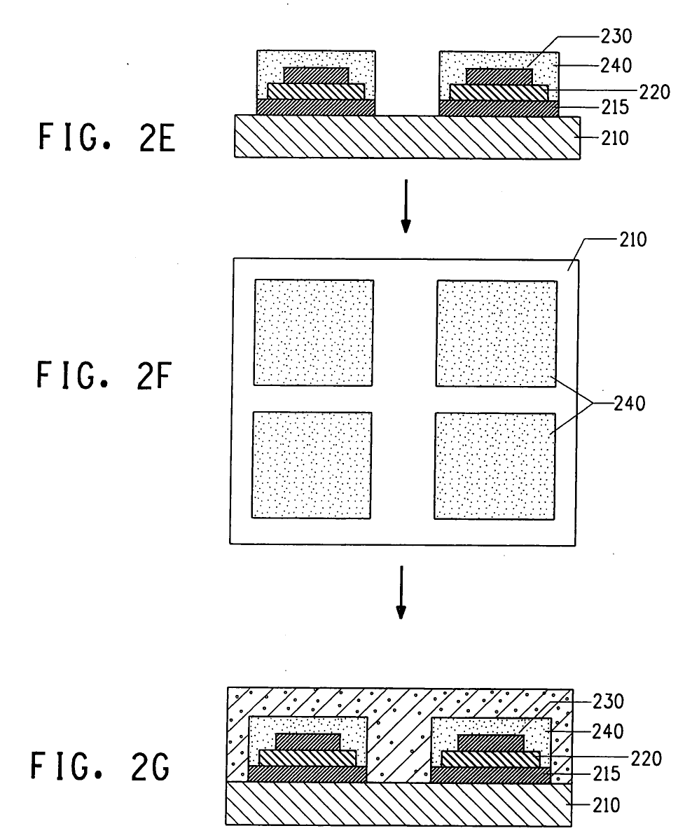

Fired-on-foil capacitors were fabricated for use as a test structure using the following process. As shown in FIG. 2A, a 1 ounce copper foil 210 was pretreated by applying copper paste EP 320 (obtainable from E. I. du Pont de Nemours and Company) as a preprint to the foil to form the pattern 215 and fired at 930° C. under copper thick-film firing conditions. Each preprint pattern was approximately 1.67 cm by 1.67 cm. A plan view of the preprint is shown in FIG. 2B.

As shown in FIG. 2c, dielectric material (EP 310 obtainable from E.I. du Pont de Nemours and Company) was screen-printed onto the preprint of the pretreated foil to form pattern 220. The area of the dielectric layer was 1.22 cm by 1.22. cm. and within the pattern of the preprint. The first dielectric layer was dried at 120° C. for 10 minutes. A second dielectric layer was then applied, and also dried using the same conditions.

As shown in FIG. 2D, copper paste EP 320 was printed over the second dielectric layer and within the area of the dielectric to form electrode pattern 230 and dried at 120° C. for 10 minutes. The area of the electrode was 0.9 cm by 0.9 cm.

The first dielectric layer, the second dielectric layer, and the copper paste electrode were then co-fired at 930° C. under copper thick-film firing conditions.

The encapsulant composition as described in Example 2 was printed through a 165 mesh screen over capacitors to form encapsulant layer 240 using the pattern as shown in FIG. 2E. The encapsulant was dried and cured using various profiles. The cured encapsulant thickness was approximately 13 microns. A plan view of the structure is shown in FIG. 2F. The component side of the foil was laminated to 1080 BT resin prepreg 250 at 375° F. at 400 psi for 90 minutes to form the structure shown in FIG. 2G. The adhesion of the prepreg to the encapsulant was tested using the IPC-TM-650 adhesion test number 2.4.9. The adhesion results are shown below:

| | Encapsulant | Encapsulant |
|---|---|---|
| Cure | over Cu | over Capacitor |
| Cycle | (lb force/inch) | (lb force/inch) |
| 190° C./30 mins | 1.2 | 3.1 |
| 190 C.°/45 mins. | 1.0 | 3.1 |
| 170° C./45 mins. | 1.0 | 1.5 |
| 120° C./60 mins | 1.2 | 3.1 |
| 170° C./90 mins | 1.2 | 3.1 |
| 200° C./5 mins | 1.2 | 3.1 |

showing that the adhesion over the capacitor and to the prepreg was quite acceptable.

### Examples 22 and 23

### Comparative Examples

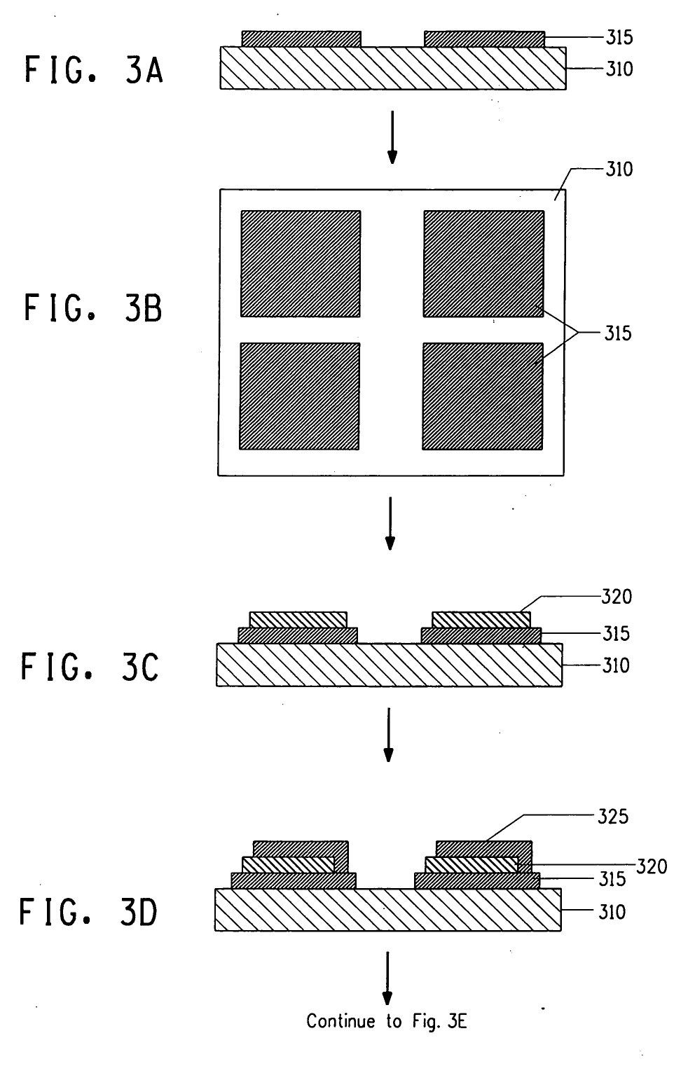

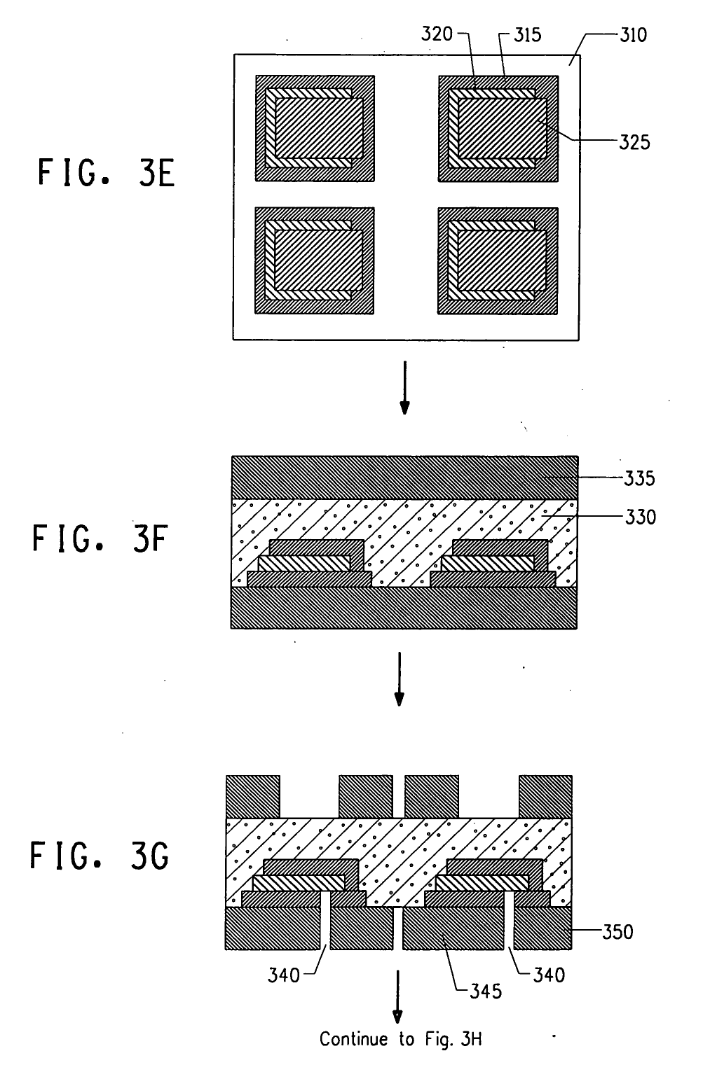

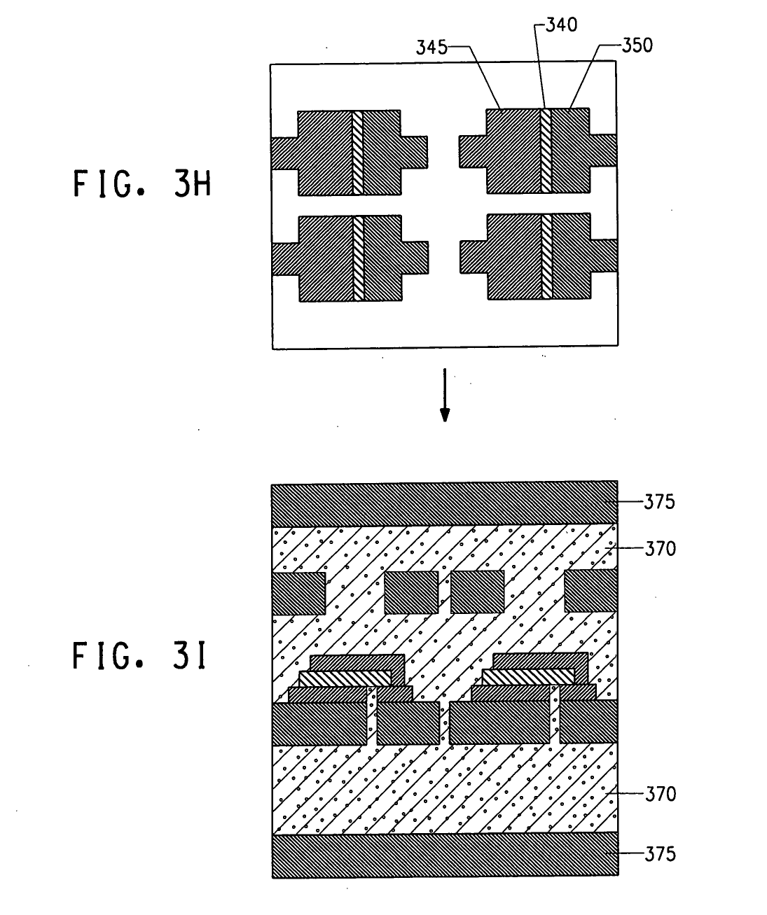

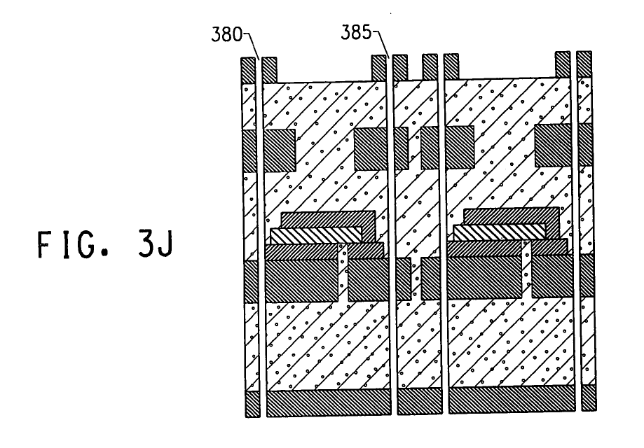

Printed wiring boards were manufactured with embedded fired-on-foil ceramic capacitors without use of an organic encapsulant. Some of the fired-on-foil capacitors were exposed to a brown oxide treatment, some were not. The printed wiring boards were fabricated, according to the process described below and as shown schematically in FIG. 3A-3J.

As shown in FIG. 3A, a 1 ounce copper foil 310 was pretreated by applying copper paste EP 320 (obtainable from E. I. du Pont de Nemours and Company) as a preprint 315 to the foil and fired at 930° C. under copper thick-film firing conditions. Each preprint pattern was approximately 150 mils by 150 mils and is shown in FIG. 3A in side elevation and as a plan view in FIG. 3B.

As shown in FIG. 3C, dielectric material (EP 310 obtainable from E.I. du Pont de Nemours and Company) was screen-printed onto the preprint of the pretreated foil to form dielectric layer 320. The area if the dielectric layer was 100 mils by 100 mils and within the pattern of the preprint. The first dielectric layer was dried at 120° C. for 10 minutes. A second dielectric layer was then applied, and also dried using the same conditions.

As shown in FIG. 3D, copper paste EP 320 was printed over the second dielectric layer and partially over the copper foil to form electrode layer 325 and dried at 120° C. for 10 minutes.

The first dielectric layer, the second dielectric layer, and the copper paste electrode layer were then co-fired at 930° C. under copper thick-film firing conditions. FIG. 3E is a plan view of the capacitor on foil structure.

In one case, foils were subjected to a brown oxide process to enhance adhesion of the copper foil to the prepreg. In another case, foils were not subjected to the brown oxide treatment prior to lamination.

The fired-on-foil capacitor side of the foil was then laminated with FR4 prepreg 330 using conventional printing wiring board lamination conditions. A copper foil 335 was also applied to the laminate material giving the laminated structure shown in FIG. 3F.

Referring to FIG. 3G, after lamination, a photo-resist was applied to the foils and the foils were imaged, etched using an alkaline etching process and the remaining photoresist stripped using standard printing wiring board processing conditions. The etching produced circuitry on the top foil and a trench 340 in the foil containing the fired-on-foil capacitors which broke electrical contact between the first electrode 310 and the second electrode 325 to form electrodes 345 and 350. This formed an inner layer panel with embedded fired-on-foil capacitors. FIG. 3H is a plan view of the foil electrode design. The inner layer panel was incorporated inside a printed wiring board containing additional prepreg 370 and copper foils 375 using standard multilayer lamination processes. As shown schematically in FIG. 3J, vias 380 and 385 were drilled and plated and the outer copper layers etched and finished with nickel/gold plating to create surface terminals connected to the capacitor.

Insulation resistance of the embedded capacitors were measured and values ranged from 50-100 Giga ohms.

Printed wiring boards containing the embedded fired-on-foil capacitors that in one case had been subjected to the brown oxide process and in another case had not been subjected to the brown oxide process were placed in an environmental chamber and the capacitors exposed to 85° C., 85% relative humidity and 5 volts DC bias. Insulation resistance of the capacitors were monitored every 24 hours. Failure of the capacitor was defined as a capacitor showing less than 50 meg-ohms in insulation resistance. Capacitors began failing for both cases after 24 hours and 100% of the capacitors for all builds failed after 120 hours.

### Example 24

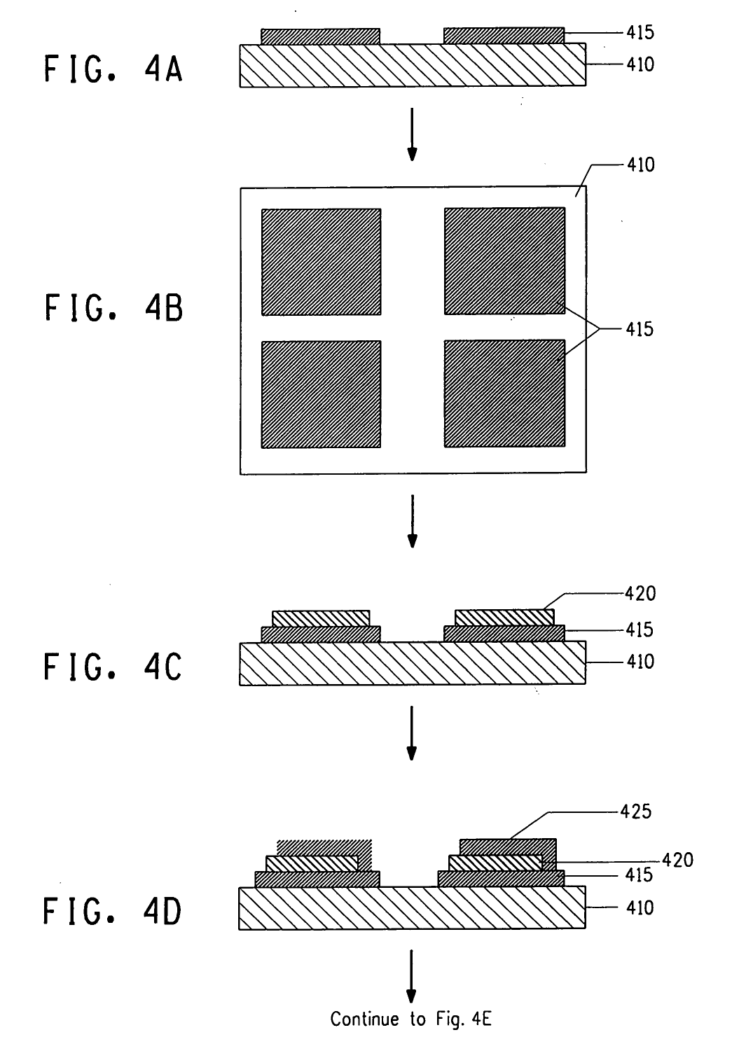

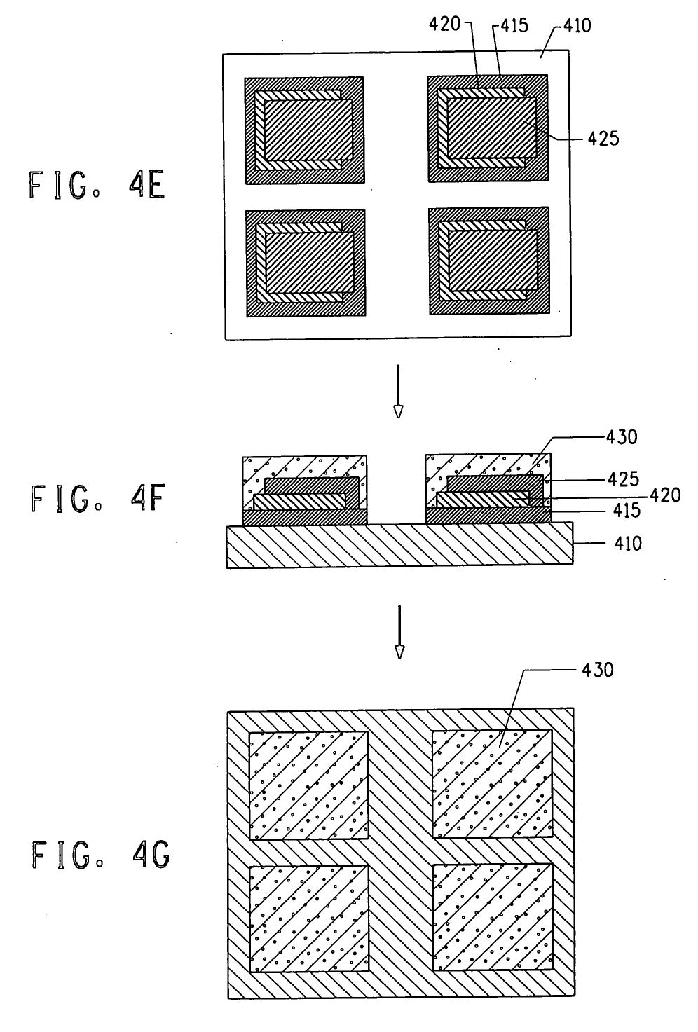

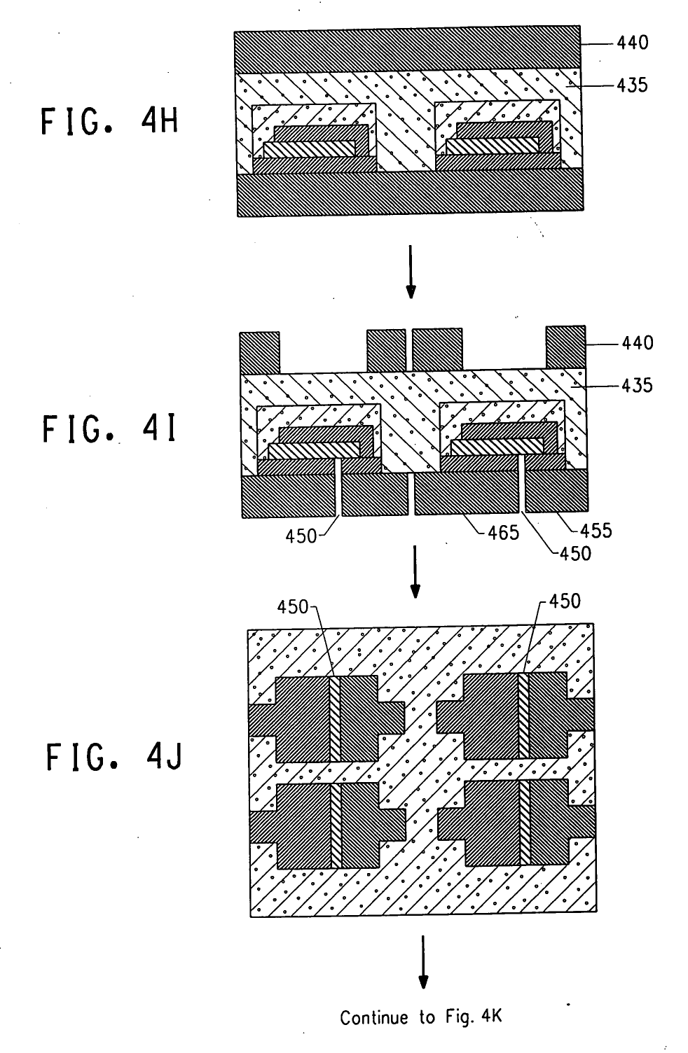

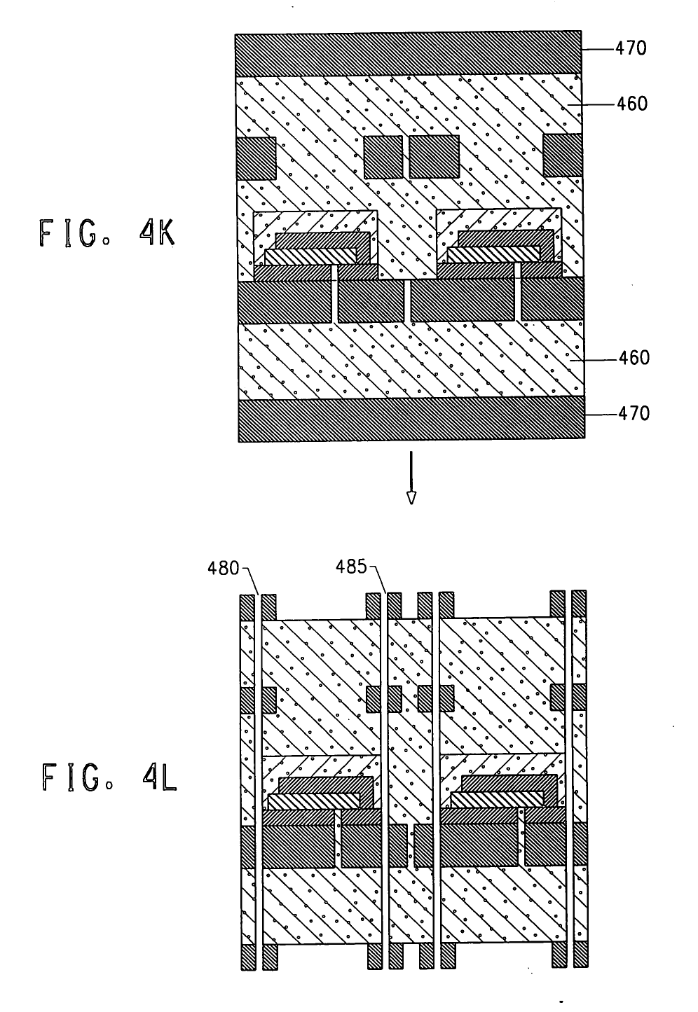

Printed wiring boards were manufactured with embedded fired-on-foil ceramic capacitors using an organic encapsulant to cover the surface of the capacitor. The printed wiring boards were fabricated, according to the process described below and as shown schematically in FIG. 4A-4L.

As shown in FIG. 4A, a 1 ounce copper foil 410 was pretreated by applying copper paste EP 320 (obtainable from E. I. du Pont de Nemours and Company) as a preprint 415 to the foil and fired at 930° C. under copper thick-film firing conditions. Each preprint pattern was approximately 150 mils by 150 mils and is shown in plan view in FIG. 4B.

As shown in FIG. 4C, dielectric material (EP 310 obtainable from E. I. du Pont de Nemours and Company) was screen-printed onto the preprint of the pretreated foil to form dielectric layer 420. The area if the dielectric layer was 100 mils by 100 mils and within the pattern of the preprint. The first dielectric layer was dried at 120° C. for 10 minutes. A second dielectric layer was then applied, and also dried using the same conditions.

As shown in FIG. 4D, copper paste EP 320 was printed over the second dielectric layer and partially over the copper foil to form electrode layer 425 and dried at 120° C. for 10 minutes.

The first dielectric layer, the second dielectric layer, and the copper paste electrode layer were then co-fired at 930° C. under copper thick-film firing conditions. FIG. 4E is a plan view of the capacitor on foil structure.

The encapsulant of example 2 was screen printed through a 400 mesh screen over the capacitor electrode and dielectric to form encapsulant layer 430 as shown in side elevation in FIG. 4F and in plan view in FIG. 4G. It was dried for 15 minutes at 120° C. Another layer of encapsulant was printed and dried for 60 minutes at 120° C. The two layers of encapsulant were then cured at 170° C. for 90 minutes followed by a short “spike” cure of 15 minutes at 200° C.

The fired-on-foil and organic encapsulant side of the foil was then laminated with FR4 prepreg 435 using conventional printing wiring board lamination conditions. No chemical brown or black oxide treatment was applied to the copper foil prior to lamination. A copper foil 440 was also applied to the laminate material giving the laminated structure shown in FIG. 4H.

Referring to FIG. 4I, after lamination, a photo-resist was applied to the foils and the foils were imaged, etched with alkaline etching processes and the remaining photoresist stripped using standard printing wiring board processing conditions. The etching produced a trench 450 in the foil containing the fired-on-foil capacitors which broke electrical contact between the foil electrode 410 and the second electrode 425 and formed electrodes 455 and 456 and an inner layer panel with embedded fired-on-foil capacitors. FIG. 4J is a plan view of the electrodes formed from the foil containing the fired-on-foil capacitors. The inner layer panel was incorporated inside a printed wiring board by lamination with additional prepreg 460 and copper foil 470 using standard multilayer lamination processes. As shown schematically in FIG. 4L, vias 480 and 485 were drilled and plated and the outer copper layers etched and finished with nickel/gold plating to create surface terminals connected to the capacitor.

Insulation resistance of the capacitors were measured and values ranged from 50-100 giga ohms.

The printed wiring board was placed in an environmental chamber and the capacitors exposed to 85° C., 85% relative humidity and 5 volts DC bias. Insulation resistance of the capacitors were monitored every 24 hours. Failure of the capacitor was defined as a capacitor showing less than 50 meg-ohms in insulation resistance. Capacitors survived 1000 hours without any noticeable degradation of insulation resistance.

### Example 25

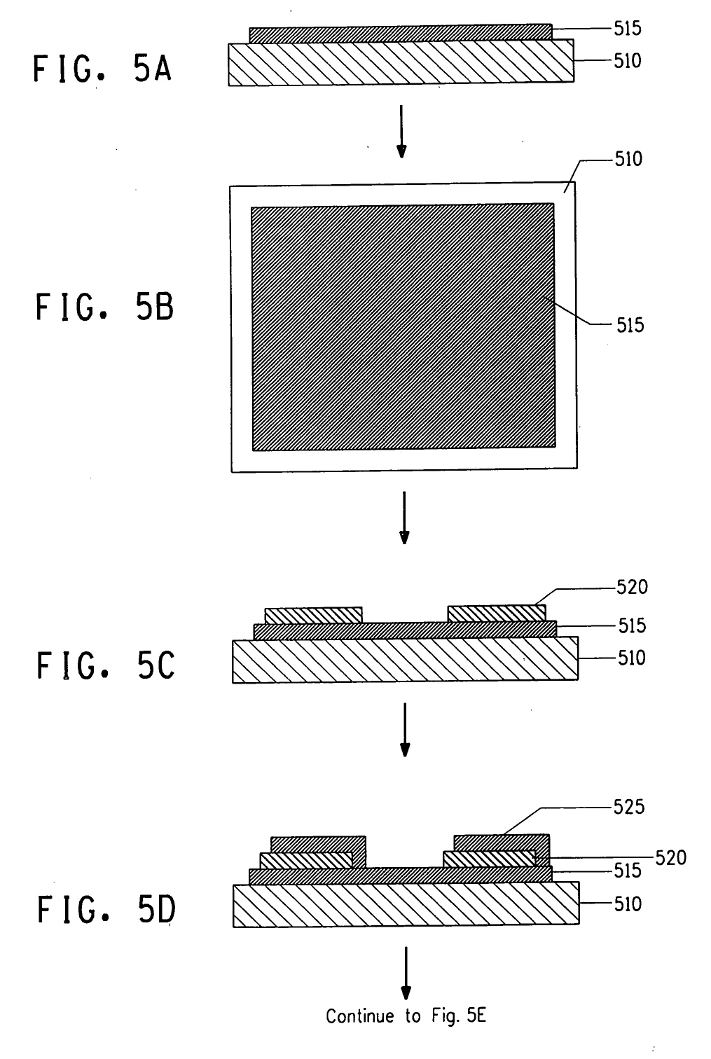

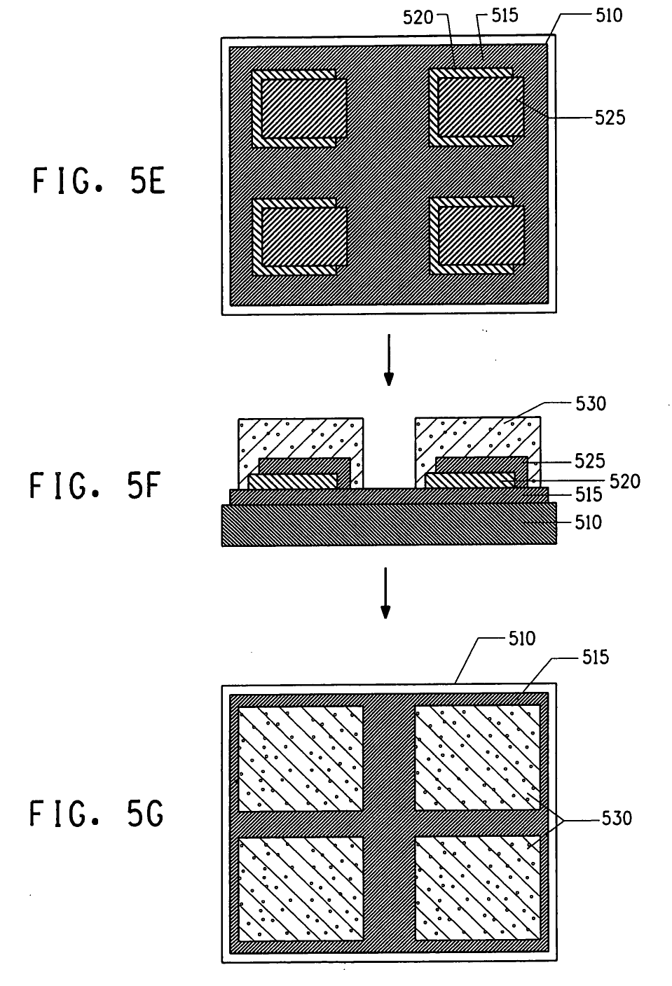

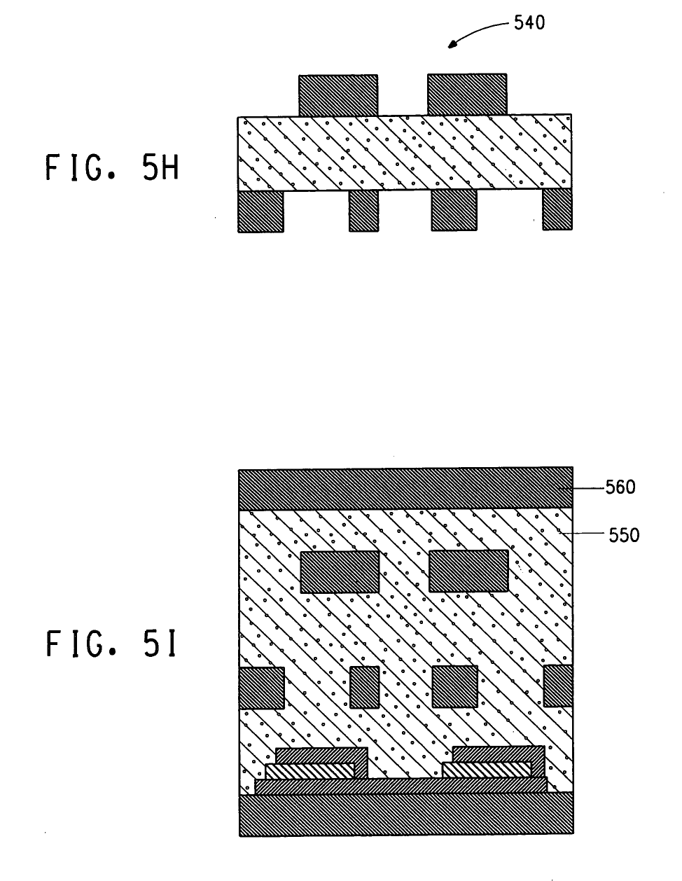

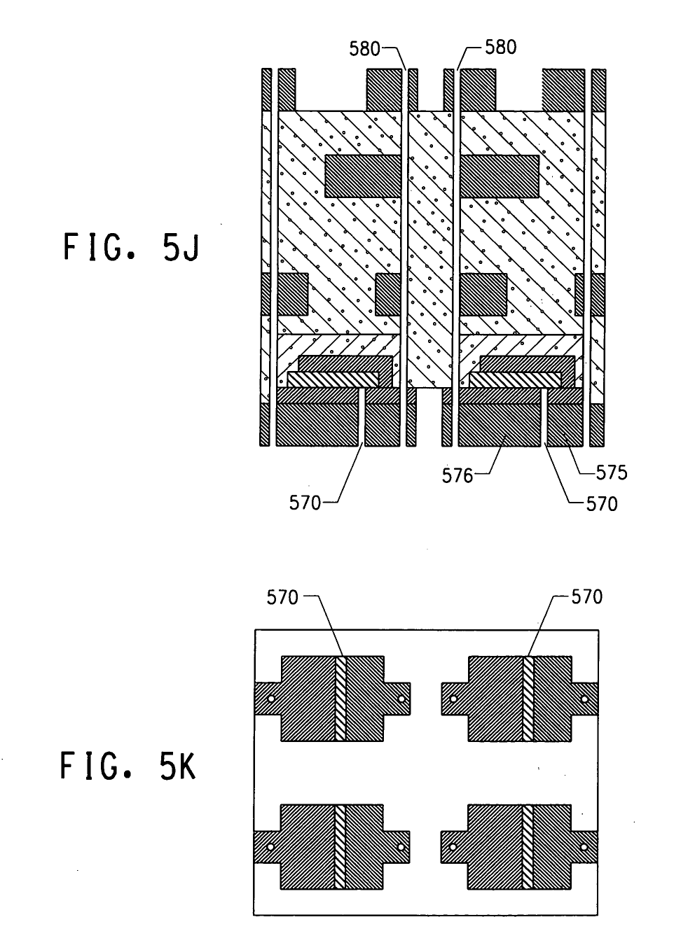

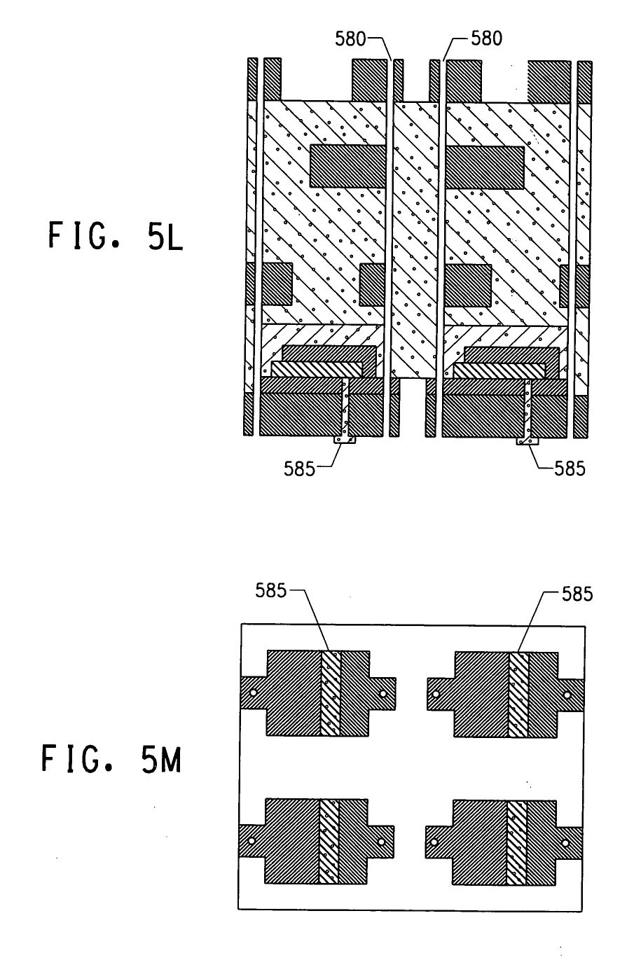

Printed wiring boards were manufactured with embedded ceramic fired-on-foil capacitors on the outer layers of the printed wiring board rather than completely embedded. In this case, the organic encapsulant was applied over the fired-on-foil capacitor and into the etched trench. The printed wiring boards were fabricated, according to the process described below and as shown in FIG. 5A-5N.

As shown in FIG. 5A, a 1 ounce copper foil 510 was pretreated by applying copper paste EP 320 (obtainable from E. I. du Pont de Nemours and Company) as a preprint 515 to the foil and fired at 930° C. under copper thick-film firing conditions. The preprint covered the entirety of the copper foil and a plan view is shown schematically in FIG. 5B.

As shown in FIG. 5C, dielectric material (EP 310 obtainable from E. I. du Pont de Nemours and Company) was screen-printed onto the preprint of the pretreated foil to form dielectric layer 520. The area if the dielectric layer was approximately 50 mils by 50 mils. The first dielectric layer was dried at 120° C. for 10 minutes. A second dielectric layer was then applied, and also dried using the same conditions.

As shown in FIG. 5D, copper paste EP 320 was printed over the second dielectric layer and partially over the preprinted copper foil to form electrode layer 525 and dried at 120° C. for 10 minutes.

The first dielectric layer, the second dielectric layer, and the copper paste electrode were then co-fired at 940° C. under copper thick-film firing conditions. FIG. 5E is a plan view of the capacitor structure.

The encapsulant of example 2 was screen printed through a 400 mesh screen over the capacitor electrode and dielectric as shown in side elevation in FIG. 5F and in plan view in 5G to form encapsulant layer 530. It was dried for 10 minutes at 120° C. Another layer of encapsulant was printed and dried for 60 minutes at 120° C. The two layers of encapsulant were then cured at 150° C. for 90 minutes followed by a short “spike” cure of 15 minutes at 200° C.

The copper foil containing the encapsulated fired-on-foil capacitors was subjected to a brown oxide treatment to enhance the adhesion of the copper foil to the prepreg material.

As shown in FIG. 5H, inner layer structure 540 was manufactured separately using prepreg and copper foils patterned and etched using standard printed wiring board processes.

The foil containing the encapsulated fired-on-foil capacitors was then laminated with FR4 prepreg with inner layer 540 and an additional laminate layer 550 and copper foil 560 to form the structure shown in FIG. 5I.

Referring to FIG. 5K, vias 580 were drilled and plated and the outer foils etched with alkaline etching processes and finished with nickel gold plating. The etching produced circuitry on the top foil and a trench 570 in the foil containing the fired-on-foil capacitors which broke electrical contact between the foil electrode 510 and the second electrode 525 to form electrodes 575 and 576. FIG. 5L is a plan view of the etched foil containing the fired-on-foil capacitors.

Referring to FIG. 5M, after forming the trench 570 in the outer foil, the encapsulant used in Example 2 was printed into the trench using a 180 mesh screen to form the structure 585. The encapsulant was dried for 10 minutes at 120° C. A second encapsulant printing was performed using the same printing conditions to insure the trench was fully filled and that part of the copper foil surrounding the trench was coated by the encapsulant. The second layer was also dried at 120° C. for 10 minutes. The encapsulant was then cured for 90 minutes at 150° C. followed by a spike cure at 200° C. for 15 minutes. A plan view of the structure is shown in FIG. 5N.

Finally, soldermask was applied to the outer surfaces to create the finished printed circuit board.

Insulation resistance of the capacitors was measured and values ranged from 10 giga-ohms to greater than 50 giga ohms.

The printed wiring board was placed in an environmental chamber and the capacitors exposed to 85° C., 85% relative humidity and 5 volts DC bias. Insulation resistance of the capacitors were monitored every 24 hours. Failure of the capacitor was defined as a capacitor showing less than 50 meg-ohms in insulation resistance. All capacitors survived 1000 hours without any noticeable degradation of insulation resistance.

We claim:

1. An organic encapsulant composition for coating embedded fired-on-foil ceramic capacitors in printed wiring boards and IC package substrates, wherein said embedded formed-on-foil ceramic capacitors comprise a capacitor and a prepreg.

2. The encapsulant composition of claim 1 wherein said encapsulant composition is cured to form a cured organic encapsulant and wherein said cured organic encapsulant provides protection to the capacitor when immersed in sulfuric acid or sodium hydroxide having concentrations of up to 30%.

3. The encapsulant composition of claim 1 wherein said encapsulant composition is cured to form a cured organic encapsulant and wherein the cured organic encapsulant provides protection to the capacitor in an accelerated life test of elevated temperatures, humidities and DC bias.

4. The encapsulant composition of claim 1 wherein the encapsulant composition is used to fill an etched trench that isolates the top and bottom electrodes of an embedded capacitor.

5. The encapsulant composition of claim 1 wherein said encapsulant composition is cured to form a cured organic encapsulant and wherein the water absorption is 1% or less.

6. The encapsulant composition of claim 1 wherein the composition can be cured at a temperature of less than or equal to 190° C.

7. The encapsulant composition of claim 1 wherein said encapsulant is cured to form a cured organic encapsulant and wherein the adhesion of said encapsulant to the capacitor and to the prepreg above the capacitor is greater than 2 lb force/inch.
